(19) United States
(12) Patent Application Publication
(10) Pub. No.: US 2002/0110995 A1
(43) Pub. Date: Aug. 15, 2002

(54) Use of discrete chemical mechanical polishing processes to form a trench isolation region

(76) Inventor: Jung-Yup Kim, Seoul (KR)

Correspondence Address: JONES VOLENTINE, L.L.C., Suite 150, 12200 Sunrise Valley Drive, Reston, VA, 20191, US

(21) Appl. No.: 09/783,042

(22) Filed: Feb. 15, 2001

(51) Int. Cl. H01L 21/76; H01L 21/302; H01L 21/461

(52) U.S. Cl. 438/427; 438/693

(57) ABSTRACT

A method of forming an trench isolation region uses discrete chemical mechanical polishing processes. Polishing stop patterns are formed on a semiconductor substrate and trenches are formed in the semiconductor substrate adjacent the polishing stop patterns. Then the polishing stop patterns are covered by and the trenches are filled with insulating material. A first chemical mechanical polishing process uses a non-ceria series slurry to partially planarize the insulating layer. Next, a second chemical mechanical polishing process uses a ceria-based slurry to planarize the insulating layer until the polishing stop patterns are exposed. The second chemical mechanical polishing process has a high polishing selectivity with respect to the material of the polishing stop patterns and the insulating material.

### BACKGROUND OF THE INVENTION

1. Field of the Invention

The present invention relates to a method of manufacturing a semiconductor device. More particularly, the present invention relates to chemical mechanical polishing process that uses a polishing pad and a supply of slurry to planarize a layer of material in the manufacturing of a semiconductor device.

2. Description of the Related Art

As semiconductor devices become more highly integrated, the wiring patterns formed on a semiconductor substrate are becoming more minute. Also, the semiconductor substrate is often times laminated with a layer of material in order to cover these minute patterns. In this case, an excessive step is formed in the layer. A planarization process, therefore, is used to remove the step and to finalize the production of the minute patterns themselves.

Chemical mechanical polishing (CMP) is often selected for use as the planarization process. In CMP, a polishing pad and a supply of slurry are used to planarize a layer of material formed on a wafer. Thus, CMP can be applied to many situations calling for a layer formed on a semiconductor substrate to be polished. For example, CMP can be used to produce an isolation region, such as a shallow trench isolation (STI) region, in a semiconductor device.

More specifically, a semiconductor substrate will be etched to form trenches therein. Then, an insulating layer, such as an oxide layer, is formed over the trenches. After that, the insulating material layer is planarized by CMP whereupon the insulating material layer is separated into respective portions occupying the trenches, whereupon the isolation region is formed. This CMP process uses a silica-based slurry.

Here, the CMP is to be stopped at the nitride silicon patterns formed on the semiconductor substrate. However, in this case, the selectivity of the CMP process, i.e., of the silica-based slurry, for silicon nitride to the silicon oxide of the insulating layer is only 1:4. Accordingly, the CMP process is not stopped entirely once the silicon nitride patterns are exposed. As the CMP process proceeds, the silicon nitride patterns are polished irregularly, meaning that the thicknesses of the silicon nitride patterns become different from each other.

Theses variations in the thickness of the silicon nitride patterns can cause problems to occur during the subsequent manufacturing process or have a degrading effect on the electrical characteristics of the semiconductor device. For example, variations in the thickness of the silicon nitride patterns can create differences in height among the portions of the insulating layer filling and hence, isolating the trenches. These differences in height can, in turn, produce a defect in a subsequently formed gate layer.

### SUMMARY OF THE INVENTION

Therefore, an object of the present invention is to solve the above-described problems of the prior art by providing a method in which the chemical mechanical polishing can be stopped with precision to prevent the polishing stop patterns from becoming irregular.

Another object of the present invention is to provide a method in which the CMP process can be carried out efficiently while also preventing the polishing stop patterns from becoming irregular.

To achieve these objects, the method of the present invention comprises two discrete chemical mechanical polishing processes. More specifically, first, trenches are formed in a semiconductor substrate, and polishing stop patterns are formed on the semiconductor substrate adjacent the trenches. Then, insulating material is deposited on the substrate to fill the trenches and cover the polishing stop patterns. Next, a first chemical mechanical polishing process uses a non-ceria series slurry to partially planarize the upper surface of the insulating layer. Then, a second chemical mechanical polishing process uses a ceria-based slurry to finalize the planarizing of the insulating layer. The second chemical mechanical polishing process is carried out until the polishing stop patterns are exposed.

The polishing stop patterns can be formed of a silicon nitride. Alternatively, the polishing stop patterns can be formed of a boron nitride or of a polysilicon. The non-ceria series slurry can be a silica-based slurry.

In any case, the non-ceria series slurry should have a selectivity that is substantially greater than 1:4 for the material of the polishing stop patterns to the insulating material. That is, the selectivity should be so high as to allow the second CMP process to be stopped once the polishing stop patterns are exposed without any residual effect of the CMP process causing irregularities to occur in the polishing stop patterns.

Moreover, the first CMP process preferably has a greater polishing rate for the insulating layer than the second CMP process. Therefore, the first CMP process removes the insulating material quickly at first, whereupon the overall time required for polishing the insulating layer is not prolonged.

### BRIEF DESCRIPTION OF THE DRAWINGS

The above and other objects, features and advantages of the present invention will become more apparent from the following detailed description of the preferred embodiment thereof made with reference to the attached drawings, of which:

FIGS. 1 through 5 are each a schematic sectional view of a semiconductor device during the manufacture of a trench isolation region thereof, and collectively illustrate a chemical mechanical polishing method according to the present invention.

### DETAILED DESCRIPTION OF THE PREFERRED EMBODIMENT

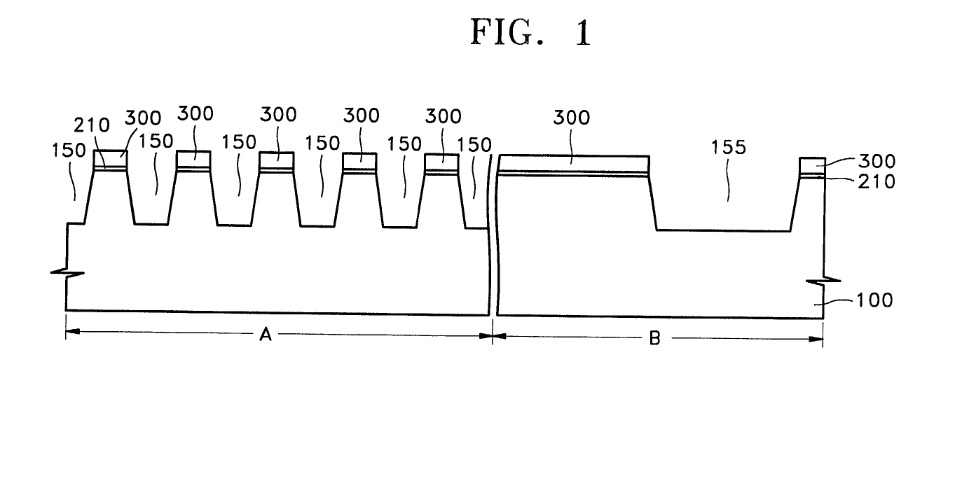

The present invention will now be described more fully with reference to FIGS. 1-5. In the drawings, the thickness of layers and regions are exaggerated for the sake of clarity. It will also be understood that when a layer is referred to as being “on” another layer or substrate, it can be disposed directly on the other layer or substrate, or intervening layers may be present therebetween.

Referring to FIG. 1, trenches 150, 155 are formed in a semiconductor substrate 100. More specifically, a polishing stop layer is formed on the semiconductor substrate 100. The polishing stop layer is then patterned so that polishing stop patterns 300 are formed. The polishing stopping patterns 300 can be formed to a thickness of about 50-500 Å. Then, the semiconductor substrate is etched to form the trenches 150, 155. In the etching process, the polishing stop patterns 300 may be used as a hard mask for forming the trenches 150, 155. Furthermore, a sacrificial insulating layer 210 can be formed at the interface between the semiconductor substrate 100 and the polishing stop patterns 300.

The trenches 150, 155, formed by selectively etching the semiconductor substrate 100 at the surfaces thereof exposed by the polishing stop patterns 300, are classified into the first trenches 150 and second trenches 155. The first trenches 150 are those trenches formed in a region (A) where the density of respective semiconductor elements is relatively high, such as a cell region where the patterns are close to one another. The second trenches 155 are those formed in a region (B) where the density of respective semiconductor elements is low compared with the cell region, such as at a peripheral circuit region or at a core region. The first trenches 150 are very narrow because the first trenches 150 are formed between the closely-spaced patterns. On the other hand, the second trenches 155 are comparatively wide.

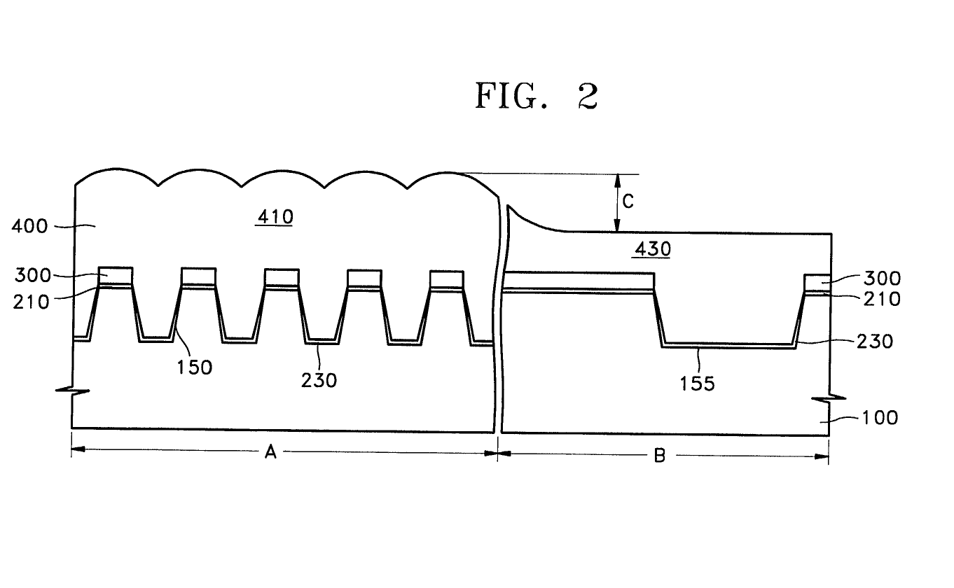

Referring to FIG. 2, an insulating layer 400 comprising an oxide layer is formed on the semiconductor substrate 100 to fill the trenches and cover the polishing stop patterns 300. More specifically, a silicon oxide layer is formed by chemical vapor deposition (CVD) over the entire surface where the polishing stop patterns 300 and the trenches 150, 155 reside. The silicon oxide layer is heat-treated for about one hour at 900˜1190° C. in an atmosphere of inert gas, such as N₂ or Ar, to increase the density of the silicon oxide layer. The densification process can be performed in a wet or dry oxidation atmosphere for a few minutes through a few hours.

Alternatively, the first and second trenches 150, 155 can be filled with a CVD oxide such as an undoped silicate glass (USG) formed of a tetra ethyl ortho silicate (TEOS), a high density plasma (HDP) oxide or a high temperature USG (formed at about 500° C.), having a good trench filling ability.

In any case, the insulating layer 400 is formed of a silicon oxide. On the other hand, the hard mask or polishing stop patterns 300 are formed of a material that can provide a polishing selectivity with respect to the silicon oxide. For instance, the polishing stop patterns can be formed of silicon nitride (SiN), boron nitride (BN), or polysilicon.

As illustrated in FIG. 2, a first portion 410 of the insulating layer 400 fills the first trenches 150 formed in the densely patterned region (A), such as the cell region. A second portion 430 of the insulating layer 400 fills the trench 155 formed in the less densely patterned region (B). The first portion 410 is thicker than the second portion 430. As an example, the first portion 410 of the insulating layer 400 is 5000 Å to 6000 Å thick.

Furthermore, as shown in FIG. 2, the top surface of the first portion 410 of the insulating layer 410 can appear as though embossed. This surface state of the first portion 410 of the insulating layer occurs mainly when an oxide layer having abundant liquidity, such as the TEOS, is used. In the case where the insulating layer 400 is formed by HDP, the surface state of the first portion 410 of the insulating layer may have a morphology opposite to that shown in FIG. 2.

The surface of the first portion 410 of the insulating layer assumes the morphology shown in FIG. 2 because of the features of the underlayer. That is, the surface morphology is dependent on the shape and density, etc. of the first trenches 150 and any intervening layer(s).

The second portion 430 of the insulating layer, formed at the core or peripheral circuit region, is thinner than the first portion 410 of the insulating layer, and has a relatively flat surface. This is because the second trench 155 underlying the second portion 430 of the insulating layer is relatively wide. And so, the relatively flat surface morphology of the second portion 430 of the insulating layer can also be said to result from the characteristics of the underlayer.

Due to this so-called underlayer dependency, the deposition of the insulating layer 400 results in a step (C) occurring between the first portion 410 and the second portion 430 of the insulating layer. As is shown in the figure, the step (C) is measured between the upper surface of the first portion 410 of the insulating layer and the upper surface of the second portion 430 of the insulating layer.

Still referring to FIG. 2, a buffer layer 230 can formed at the side walls and/or bottom of the first and second trenches 150,155 before the insulating layer 400 is formed. Specifically, the silicon of the semiconductor substrate 100 that defines the side walls and/or bottom of the first and second trenches 150, 155 is oxidized to produce a thin (30˜500 Å) thermal oxide layer constituting the buffer layer 230. The buffer layer 230 is provided for curing the surface damage that occurs during the etching of the substrate 100 to form the trenches 150, 155, for preventing current from leaking through the silicon surface of the semiconductor substrate 100 defining the trenches 150, 155, and for preventing a stress concentrations at the bottom corners of the trenches 150, 155 by producing curved surfaces at the corners. The buffer layer 230 can also include a silicon nitride liner on the thermal oxide layer.

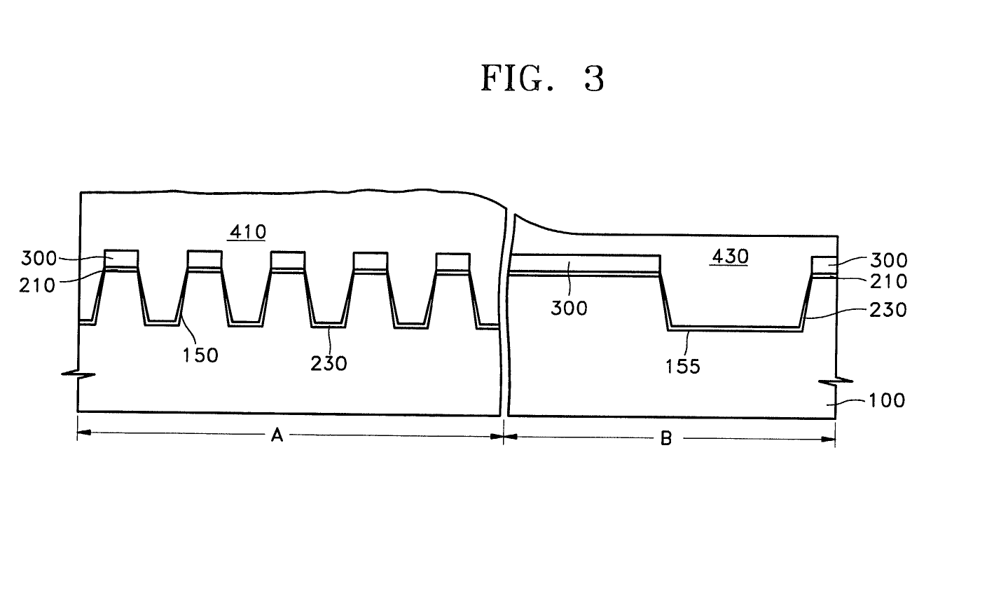

Referring now to FIG. 3, a first CMP process is performed on the insulating layer 400 whereupon at least the first portion 410 of the insulating layer exhibiting an embossed state or minute bosses is locally planarized. In particular, the first CMP process is performed on the insulating layer 400 using a non-ceria series slurry such as a silica-based slurry.

A silica-based slurry refers to a slurry using particles of silica as an abrasive. For example, SS-25 marketed by Cabot can be used as the silica-based slurry. In this case, the silica-based slurry has a pH of about 11. Furthermore, silica-based slurry has relatively low dependency on the surface state of the material being polished. Therefore, if the surface exhibits an embossed state or minute bosses as described above, a CMP process using a silica-based slurry will alleviate the embossed state or sufficiently remove the minute bosses, i.e., a partially planarized surface can be achieved.

The first portion 410 of the insulating layer can be partially planarized by the first CMP process, and the second portion 430 of the insulating layer can be polished to some degree as well. However, the first portion 410 of the insulating layer is polished at a greater rate. Therefore, as the polishing process progresses, the step (C) between the first portion 410 and second portion 430 of the insulating layer is gradually reduced.

As mentioned above, the first CMP process is preferably performed to partially planarize the surface of the first portion 410 of the insulating layer as described above. For example, the first CMP process can be performed until the first portion 410 of the insulating layer becomes 2000 Å to 5000 Å thick.

As also mentioned above, a CMP process using a silica-based slurry has a relatively low dependency on the surface state of the material being polished. Therefore, the first CMP process is effective for removing the minute bosses or the unevenness in the surface of the first portion 410 of the insulating layer. However, a CMP process using a silica-based slurry can not be stopped in a controlled manner.

For example, a CMP process using a silica-based slurry can remove silicon oxide at a rate (polishing removal rate) of about 2000 Å/min and can remove silicon nitride at a polishing removal rate of about 500 Å/min. That is, the selectivity of the process with respect to silicon nitride and silicon oxide is merely about 1:4. This selectivity is an obstacle to the polishing stop patterns 300 in facilitating a satisfactory stop effect.

Also, the rate at which silicon oxide can be removed by the CMP process using the silica-based slurry has a tendency to rapidly decline over time. That is, the silicon oxide polishing removal rate can be relatively high during the beginning stage of a CMP process using a silica-based slurry, but after that the polishing removal rate decreases rapidly.

Therefore, the first CMP process using the silica-based slurry is preferably performed for a time necessary only to partially planarize the surface of the first portion 410 of the insulating layer.

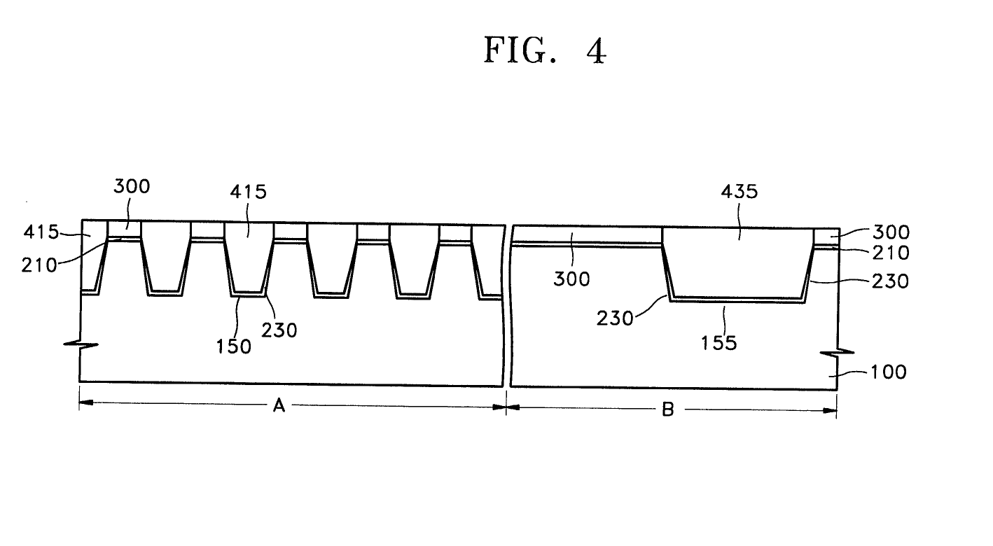

Referring now to FIG. 4, a second CMP process using a ceria (CeO₂) based slurry is performed after the surface of the first portion 410 of the insulating layer is partially planarized. The second CMP process is stopped once the upper surface of the polishing stop patterns 300 is exposed.

A ceria-based slurry refers to a slurry using ceria as an abrasive. In the preferred embodiment of the present invention, HS-8005 (abrasive) and HS-8102GP (chemical solvent) marketed by Hitachi is used as the ceria-based slurry. The pH of the slurry is about 7 to 8.5, but ceria-based slurries having a pH of as low as about 3.5 can be used as well.

Ceria-based slurry is known to have a layer material dependency when used for polishing. In particular, ceria-based slurry is known have a very low polishing removal rate when the surface of the material being polished is uneven. Accordingly, if a CMP process using a ceria-based slurry were performed on the surface of the first portion 410 of the insulating layer just after the insulating layer was formed, the polishing removal rate would be very low and thus, it would take a long time to polish the insulating layer 400 to a satisfactory extent.

However, a ceria-based slurry can exhibit a very high selectivity for silicon nitride to silicon oxide of, for example, about 1:40. In the preferred embodiment of the present invention, the second CMP process using a ceria-based slurry can achieve a polishing removal rate for silicon oxide of 3000 Å/min and a polishing removal rate for silicon nitride of 30 Å/min . Also, the CMP process using the ceria-based slurry has a characteristic in that the polishing removal rate remains relatively constant over time.

In the preferred embodiment of the present invention, the partially planarized insulating layer 400 is polished using the ceria-based slurry. The polishing stops once the polishing stop patterns 300 become exposed. A satisfactory polishing stop feature is facilitated by the polishing stop patterns 300 because the CMP process using the ceria-based slurry exhibits the high selectivity described above. Therefore, the thickness of the polishing stop patterns 300 remains uniform, i.e., the polishing stop patterns 300 exhibit no irregularities concerning their shape and thickness. Consequently, the isolation patterns 415, 435 formed in the respective trenches 150, 155 by polishing the insulating layer 400 have a uniform height.

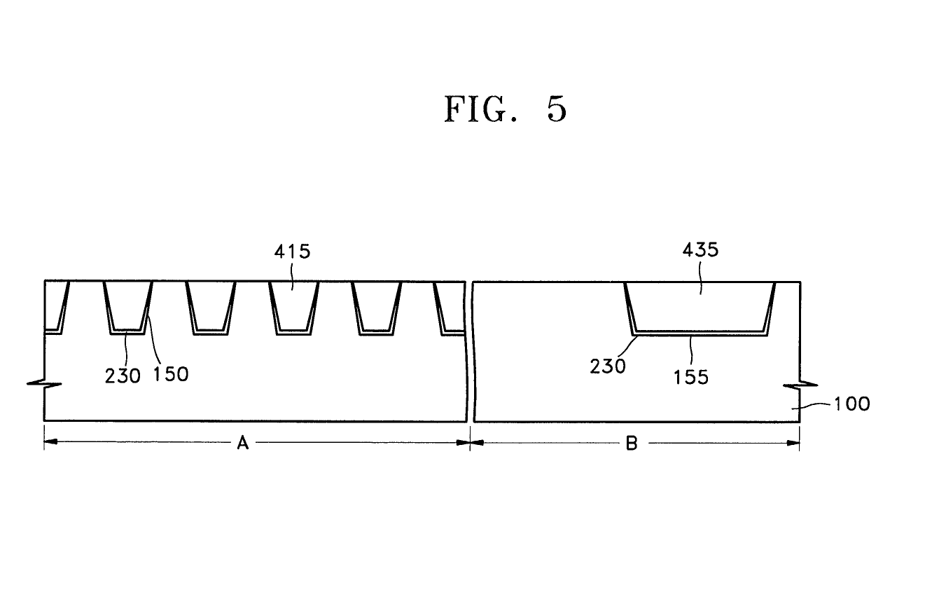

Referring to FIG. 5, next, the polishing stop patterns 300 and the sacrificial insulating layer 210 are removed. Subsequently, the resulting structure is cleaned with a phosphoric acid solution and B.O.E. Then, a sacrificial oxide layer (not shown) is grown and wet etched again, whereby the isolation patterns 415, 435 are completed.

As described above, the method of forming the STI region includes a first CMP process using a non-ceria series slurry, for example, a silica-based slurry, and a second CMP process using a ceria-based slurry. Accordingly, the entire CMP process can be performed in a short amount of time. Furthermore, the process has a satisfactory polishing stop feature. Accordingly, the features of the STI region or like features of the semiconductor device are excellent.

Finally, although the present invention has been described with respect to the preferred embodiments thereof, the invention may be embodied in different forms readily apparent to those skilled in the art. Accordingly, all such forms of the present invention are seen to be within the true spirit and scope of the invention as defined by the appended claims.

What is claimed is:

1. A method of forming a trench insolation region of a semiconductor device, said method comprising the steps of:
forming polishing stop patterns of a first material on a semiconductor substrate;
forming trenches in the semiconductor substrate adjacent the polishing stop patterns;
covering the polishing stop patterns and filling up the trenches with insulating material to form an insulating layer;
chemical mechanical polishing the insulating layer using a non-ceria series slurry only until the surface of the insulating layer is partially planarized; and
subsequently chemical mechanical polishing the surface of the partially planarized insulating layer using a ceria-based slurry, having a polishing selectivity substantially greater than 1:4 for the material of the polishing stop patterns to the insulating material, until the polishing stop patterns are exposed.

2. The method of claim 1, wherein the forming of the polishing stop patterns comprises forming patterns of nitride silicon.

3. The method of claim 1, wherein the forming of the polishing stop patterns comprises forming patterns of boron nitride.

4. The method of claim 1, wherein the forming of the polishing stop patterns comprises forming patterns of polysilicon.

5. The method of claim 1, wherein the chemical mechanical polishing of the insulating layer is performed using a silica-based slurry.

6. A method of forming a trench isolation region of a semiconductor device, the method comprising the steps of:
forming polishing stop patterns of a first material on a semiconductor substrate;
forming trenches in the semiconductor substrate adjacent the polishing stop patterns;
covering the polishing stop patterns and filling up the trenches with insulating material, having an underlayer dependency, to form an insulating layer, whereby the upper surface of the insulating layer has a degree of unevenness;
chemical mechanical polishing the insulating layer using a non-ceria series slurry until the unevenness existing at the upper surface of the filling insulating layer is reduced; and
subsequently chemical mechanical polishing the upper surface of the insulating layer using a ceria-based slurry until the polishing stop patterns are exposed.

7. The method of claim 6, wherein the forming of the polishing stop patterns comprises forming patterns of nitride silicon.

8. The method of claim 6, wherein the forming of the polishing stop patterns comprises forming patterns of boron nitride.

9. The method of claim 6, wherein the forming of the polishing stop patterns comprises forming patterns of polysilicon.

10. The method of claim 6, wherein the chemical mechanical polishing of the insulating layer is performed using a silica-based slurry.
